(19) United States
(12) Patent Application Publication
(10) Pub. No.: US 2021/0320002 A1
(43) Pub. Date: Oct. 14, 2021

(54) WATER SOLUBLE POLYMERS FOR PATTERN COLLAPSE MITIGATION

(71) Applicant: Honeywell International Inc., Morris Plains, NJ (US)

(72) Inventors: Desaraju VARAPRASAD, Morris Plains, NJ (US); Songyuan XIE, Morris Plains, NJ (US)

(21) Appl. No.: 17/272,081

(22) PCT Filed: Aug. 22, 2019
(86) PCT No.: PCT/US2019/047676

§ 371 Date: Feb. 26, 2021

Related U.S. Application Data
(60) Provisional application No. 62/725,573, filed on Aug. 31, 2018.

(51) Int. Cl. H01L 21/02; G03F 7/40

(52) U.S. Cl. CPC H01L 21/02071; G03F 7/40; H01L 21/31138; H01L 21/02282; H01L 21/02356; H01L 21/02118

(57) ABSTRACT

A method for preventing the collapse of patterned, high aspect ratio features formed in semiconductor substrates upon removal of an initial fluid of the type used to clean etch residues from the spaces between the features. In the present method, the spaces are at least partially filled with a displacement solution, such as via spin coating, to substantially displace the initial fluid. The displacement solution includes at least one solvent and at least one fill material in the form of a water-soluble polymer such as polyvinylpyrrolidone (PVP) or polyacrylamide (PAAM). The solvent is then volatized to deposit the fill material in substantially solid form within the spaces. The fill material may be removed by known plasma ash process via a high ash rate as compared to use of current fill materials, which prevents or mitigates silicon loss.

### BACKGROUND

### 1. Field of the Disclosure

The present disclosure relates to the manufacture of electronic components via photolithography techniques, and the mitigation or prevention of collapse, or stiction, which may occur between pattered, high aspect ratio features of semiconductor substrates upon removal of aqueous wash solutions of the type used to remove ash residue.

### 2. Description of the Related Art

During manufacture of electronic components, such as memory cells and other components built on a semiconductor substrate, such as a pure or doped silicon wafer, the substrate is processed using photolithography techniques. For example, a photoresist may be deposited onto a flat silicon wafer, followed by patterning the photoresist using UV exposure, for example. Then, the photoresist is developed to facilitate removal of portions of the photoresist corresponding to the locations of trenches formed between narrow or high aspect ratio features formed on the substrate.

Next, an etching process, such as a plasma etch, is used to etch the trenches into the silicon wafer between the remaining photoresist portions, followed by removing the remaining photoresist and any remaining etchant or other debris using a wash solution which is typically an aqueous solution. In this manner, after the wash step, a series of elongated, vertically-disposed high aspect ratio silicon features are present which extend from the underlying silicon wafer, with the wash solution disposed within the trenches or spaces between the silicon features.

Problematically, as shown in FIG. 1, direct evaporation of the wash solution at this stage tends to cause the patterned, high aspect ratio features to collapse on one another due to effects of the surface tension and capillary forces of the water of the wash solution. Collapse of high aspect ratio features concurrent with wash solution removal is a common failure mode in high resolution photolithography, particularly in less than 0.1 micron photolithography techniques, and is sometimes referred to as “stiction”. To mitigate collapse of patterns during wafer drying, rinsing with isopropyl alcohol (IPA) and/or surface modification treatments may be employed. While these methods are successful in some pattern designs, in more recent, advanced designs of high aspect ratio nanostructures preventing collapse of structures continues to be a challenge.

In other methods of overcoming stiction-induced collapse of high aspect ratio features, a displacement solution of polymer fill may be introduced into the spaces between the high aspect ratio features to substantially displace the wash solution. Then, volatile components of the displacement solution are removed with heat treatment, with the polymer remaining within the spaces in substantially solid form to support the high aspect ratio features. The polymer is then removed using removal processes such as plasma ashing, with oxygen- or hydrogen-based plasma in conjunction with nitrogen or helium, for example.

However, polymer fill materials and plasma-based processes may potentially lead to the loss of silicon due to oxidation or nitridation of the high aspect ratio features, and many advanced memory designs are not able to tolerate such loss of silicon due to chemical conversion during the removal of polymer fills using plasma ashing process. Other advanced memory designs, such as transistor-less 3D-XPoint memory technology, cannot tolerate current plasma ashing processes for removal of current polymer fills used for stiction control.

### SUMMARY

The present disclosure provides a method for preventing the collapse of patterned, high aspect ratio features formed in semiconductor substrates upon removal of an initial fluid of the type used to clean etch residues from the spaces between the features. In the present method, the spaces are at least partially filled with a displacement solution, such as via spin coating, to substantially displace the initial fluid. The displacement solution includes at least one solvent and at least one fill material in the form of a water-soluble polymer such as polyvinylpyrrolidone (PVP) or polyacrylamide (PAAM). The solvent is then volatized to deposit the fill material in substantially solid form within the spaces. The fill material may be removed by known plasma ash process via a high ash rate as compared to use of current fill materials, which prevents or mitigates silicon loss.

In one form thereof, the present disclosure provides a method for preventing collapse of semiconductor substrate features, including the steps of: providing a patterned semiconductor substrate having a plurality of high aspect ratio features with spaces between the features, the gap spaces at least partially filled with an initial fluid; displacing the initial fluid with a displacement solution including at least one primary solvent and at least one first fill material in the form of a water-soluble polymer having a weight average molecular weight (Mw) between 1,000 and 15,000 Daltons, as determined by gel permeation chromatography (GPC), the displacement solution further having a viscosity of less than 100 centipoise; exposing the substrate to an elevated temperature to substantially remove the solvent from the spaces and deposit the fill material in substantially solid form within the spaces; and exposing the substrate to a dry ash process to remove the fill material from the gap spaces.

The at least one water-soluble polymer may be selected from the group consisting of polyvinylpyrrolidone (PVP), polyacrylamide (PAAM), and a combination thereof.

The elevated temperature may be between 100° C. and 280° C. The at least one solvent may be water, may be at least one non-aqueous solvent, or may be water and at least one non-aqueous solvent.

The displacement solution may further include at least one secondary solvent and at least one surfactant. The displacement step may be carried out via spin coating.

The displacement solution may include between 5 wt. % and 30 wt. % of the fill material, based on the total weight of the displacement solution. The displacement solution has a viscosity of less than 50 centipoise.

The exposing steps may be conducted in one of an ambient air atmosphere and an atmosphere of an inert gas.

In another form thereof, the present invention provides a displacement solution for use in preventing collapse of semiconductor substrate features, including: at least one water-soluble polymer having a weight average molecular weight (Mw) between 1,000 and 15,000 Daltons, as determined by gel permeation chromatography (GPC); at least one primary solvent; at least one secondary solvent; at least on surfactant; and the displacement solution having a viscosity of less than 100 centipoise.

The at least one water-soluble polymer may be selected from the group consisting of polyvinylpyrrolidone (PVP), polyacrylamide (PAAM), and a combination thereof. The at least one polymer may be present in an amount of between 5 wt. % and 30 wt. %, based on an overall weight of the displacement solution.

The at least one primary solvent may be present in an amount of between 70 wt. % and 95 wt. %, based on an overall weight of the displacement solution. The at least one secondary solvent may be present in an amount of between 1 wt. % and 10 wt. %, based on an overall weight of the displacement solution.

The at least one water-soluble polymer may have a weight average molecular weight (Mw) between 2,500 and 10,000 Daltons, as determined by gel permeation chromatography (GPC). The at least one water-soluble polymer may have a weight average molecular weight between 4,000 and 6,000 Daltons, as determined by gel permeation chromatography (GPC).

The displacement solution may have a viscosity less than 50 centipoise, or may have a viscosity less than 10 centipoise.

### BRIEF DESCRIPTION OF THE DRAWINGS

The above mentioned and other features of the disclosure, and the manner of attaining them, will become more apparent and the disclosure itself will be better understood by reference to the following description of embodiments of the disclosure taken in conjunction with the accompanying drawings.

FIG. 1 is a sectional view of a semiconductor substrate which has been patterned to form high aspect ratio features, showing collapse of the features upon water removal according to prior processes;

FIG. 2 is a view of a semiconductor substrate with high aspect ratio features after photolithographic pattering, additionally showing an initial fluid disposed within the spaces between the features after etch residues are removed;

FIG. 3 schematically shows the displacement of the initial fluid from the spaces between the high aspect ratio features using a displacement solution in accordance with present disclosure;

FIG. 4 shows fill materials in substantially solid form in the spaces between the high aspect ratio features after removal of the solvent from the displacement solution, with the fill materials either partially filling the spaces (at left) or completely filling the spaces (at right);

FIG. 5 shows the silicon substrate and high aspect ratio features after removal of the fill materials;

FIG. 6 corresponds to Example 1, and shows viscosity vs. concentration data;

FIG. 7 corresponds to Example 1, and shows viscosity vs. concentration data;

FIG. 8 corresponds to Example 1, showing film thickness vs. spin speed data; and

FIG. 9 corresponds to Example 1, showing film thickness vs. spin speed data.

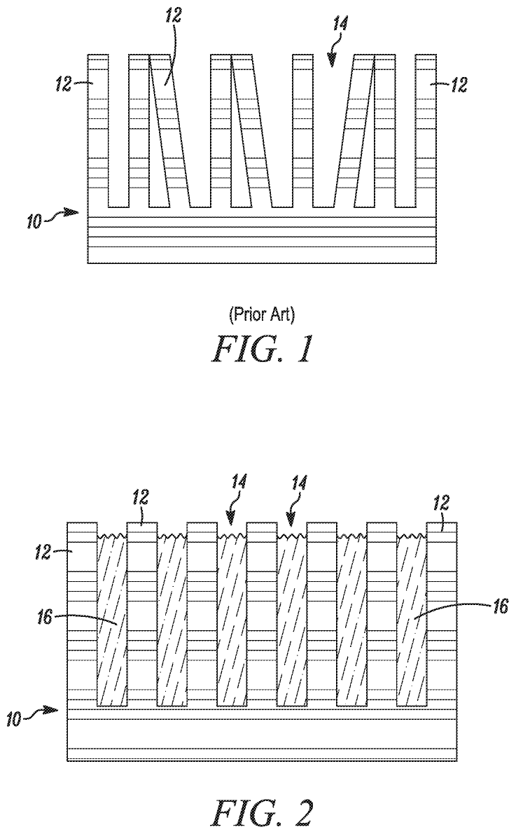

Corresponding reference characters indicate corresponding parts throughout the several views. The exemplifications set out herein are provided to illustrate certain exemplary embodiments and such exemplifications are not to be construed as limiting the scope in any manner.

### DETAILED DESCRIPTION

Referring to FIG. 2, a semiconductor substrate 10, such as a pure or doped silicon wafer, is shown, which has been pattered using photolithography techniques to form a number of high aspect ratio features 12, such as pillars or columns, having spaces 14, such as lines or trenches, therebetween. Features 12 may have an aspect ratio of height to width greater than 4:1, or even 10:1 or greater, for example. In FIG. 2, substrate 10 is shown at a stage in which an initial fluid 16 of the type used to clean photolithographic etch residues, is disposed within spaces 14 between the high aspect ratio features 12. As described further below, the initial fluid 16 is displaced by a displacement solution according to the present disclosure.

The fill materials disclosed herein may be either polymers or oligomers of varying molecular weight and, for the purposes of the present disclose, the term “polymer” generally encompasses molecules having a plurality of repeat units, including both polymers and oligomers.

The present displacement solution includes at least one first fill material in the form of at least one water-soluble polymer. The water-soluble polymer may be selected from the group consisting of polyvinylpyrrolidone (PVP), polyacrylamide (PAAM), polyvinyl alcohol (PVA), and combinations thereof.

PVP has the chemical structure set forth below in Formula (I):

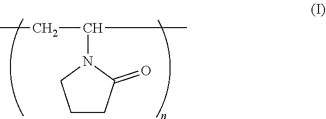

PAAM has the chemical structure set forth below in Formula (II):

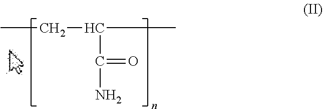

PVA has the chemical structure set forth below in Formula (III):

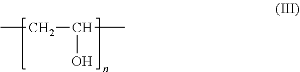

Of the foregoing polymers, each of PVP and PAAM include nitrogen-containing pendant functional groups, which is thought to facilitate water solubility, with the foregoing polymers having a nitrogen content of as little as 5 wt. %, 10 wt. % or 12 wt. %, or as great as 20 wt. %, 25 wt. % or 30 wt. %, or within any range defined between any two of the foregoing values, such as 5 wt. % to 30 wt. %, 10 wt. % to 25 wt. % or 12 wt. % to 20 wt. %, based on the total weight of all atoms in each repeating unit of the polymer.

The polymer may have a weight average molecular weight (Mw), as determined by gel permeation chromatography (GPC), of as little as 1,000 Daltons, 1,500 Daltons, or 4,000 Daltons, or as high as 6,000 Daltons, 10,000 Daltons, or 15,000 Daltons, or within any range defined between any two of the foregoing values, such as 1,000 to 15,000 Daltons, 2,500 to 10,000 Daltons, or 4,000 to 6,000 Daltons, for example.

Typically, the total amount of the fill material in the displacement solution, based on the overall weight of the displacement solution, may be as little as 5 wt. %, 10 wt. %, or 15 wt. %, or as great as 20 wt. %, 25 wt. %, or 30 wt. %, or may be within any range defined between any pair of the foregoing values, such as between 5 wt. % and 30 wt. %, between 10 wt. % and 25 wt. %, or between 15 wt. % and 20 wt. %, for example, based on the total weight of the displacement solution, with the remainder of the displacement solution being one or more solvents and/or other additives such as those discussed below.

The displacement solution also includes at least one primary solvent, which may be water only, may be one or more non-aqueous solvents such as isopropyl alcohol (IPA), n-propyl alcohol (n-PA), n-methyl-2-pyrrolidone (NMP), and dimethylformamide (DMF), or may be a blend of water and at least one non-aqueous solvent. The primary solvent functions to solvate the polymer and is volatized during heat treatment after the displacement solution is applied. The primary solvent is the majority component of the displacement solution based on weight percent, and may be present in an amount as little as 70 wt. %, 75 wt. %, or 80 wt. %, or as great as 85 wt. %, 90 wt. %, or 95 wt. %, or may be present within any range defined between any pair of the foregoing values, such as between 70 wt. % and 95 wt. %, between 75 wt. % and 90 wt. %, or between 80 wt. % and 85 wt. %, for example, based on the total weight of the displacement solution.

The displacement solution may optionally also include at least one secondary solvent such as propylene glycol methyl ether acetate (PGMEA), propylene glycol (PG), propylene glycol propyl ether (PGPE) and propylene glycol methyl ether (PGME), for example. The secondary solvent aids in film-forming by improving the wetting characteristics of the formulation as a carrier for the surfactant. The secondary solvent is present as a minority component of the displacement solution based on weight percent, and may be present in an amount as little as 1.0 wt. %, 2.0 wt. %, or 3.0 wt. %, or as great as 5.0 wt. %, 7.5 wt. %, or 10 wt. %, or may be present within any range defined between any pair of the foregoing values, such as between 70 wt. % and 95 wt. %, between 75 wt. % and 90 wt. %, or between 80 wt. % and 85 wt. %, for example, based on the total weight of the displacement solution.

Other components of the displacement solution may include one or more surfactants, such as non-fluorinated hydrocarbons, fluorinated hydrocarbons, or combinations thereof, typically present in a total amount of as little as 0.1 wt. %, 0.5 wt. %, or 1.0 wt. %, or as great as 1.5 wt. %, 2.0 wt. %, or 3 wt. %, or may be present within any range defined between any pair of the foregoing values, such as between 0.1 wt. % and 3 wt. %, between 0.5 wt. % and 2.0 wt. %, or between 1.0 wt. % and 1.5 wt. %, for example, based on the total weight of the displacement solution. One suitable surfactant is a non-ionic polymeric fluorochemical surfactant such as Novec™ FC-4430 fluorosurfactant, available from 3M of Maplewood, Minn.

The components of the displacement solution may be blended together with simple mixing, for example. When mixed, the displacement solution may have a viscosity less than 100 centipoise, less than 50 centipoise, or less than 10 centipoise, for example, as determined by a Brookfield LVDV-II-PCP or DV-II+ spindle-type viscometer. Advantageously, the relatively low viscosity of the present displacement solution allows same to easily displace initial wash solutions and to fill within the spaces between high aspect ratio features of silicon wafer substrates in the manner described below. If the viscosity of the displacement solution is too high, the fill material of the displacement solution may tend to bridge, or overlap, adjacent high aspect ratio features of the silicon wafer substrate rather than filling within the spaces between the high aspect ratio features.

Referring to FIGS. 2-5 below, an exemplary method of using the present displacement solution is described. In FIG. 2, substrate 10 is shown at a stage following completion of one or more photolithography processes, in which an initial fluid 16 is disposed within the spaces 14 between the high aspect ratio features 12. In one embodiment, the initial fluid 16 may be an aqueous wash solution of the type used to remove photolithographic etch residues. Typically, the aqueous wash solution will be primarily an aqueous solution including dissolved or particulate etch residues, and may either partially or completely fill the spaces between the high aspect ratio features.

In an optional first step, the initial fluid 16 is a flushing solvent or flushing solution, which is non-aqueous and is a mutual solvent for both water and the fill materials disclosed herein. The flushing solution may include isopropyl alcohol (IPA), acetone, or ethyl lactate, for example, and may be used to displace the aqueous wash solution prior to displacement of the flushing solution using the displacement solution of the present disclosure.

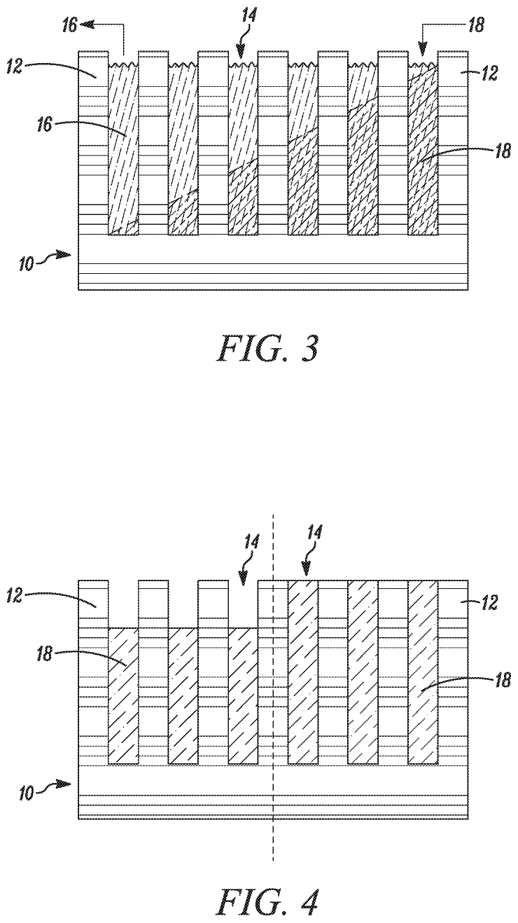

Referring to FIG. 3, the displacement solution 18 in accordance with the present disclosure is applied to substrate 10 to volumetrically displace the initial fluid 16 which, as described above, may be in the form of an aqueous wash solution or the initial flushing solution. The displacement solution 18 may be applied to substrate 10 via spin coating, in which the volume of displacement solution applied is sufficient to completely, or substantially completely, volumetrically displace and remove the initial fluid 16, as schematically shown by the dashed diagonal line in the arrows in FIG. 3, in which the displacement solution is spin-coated into spaces 14 between features 12 and displaces the initial fluid 16. Suitable spin speeds may be as little as 500 rpm, 1000 rpm, or 1,500 rpm, or as high as 2,000 rpm, 2,500 rpm, or 3,000 rpm, or may be within any range defined between any pair of the foregoing values, such as between 500 rpm and 3,000 rpm, between 1,000 rpm and 2,500 rpm, or between 1,500 rpm and 2,000 rpm, for example. In this manner, with continued reference to FIG. 3, the spaces 14 between high aspect ratio features 12 are either completely filled, or substantially filled, with the displacement solution 16.

Next, the substrate 10 is exposed to a first heat treatment step at a first elevated temperature which may be as low as 100° C., 125° C., or 150° C., or as high as 200° C., 240° C., or 280° C., or may be within any range defined between any two of the foregoing values, such as 100° C. to 280° C., 125° C. to 240° C. or 150° C. to 200° C., for example. In this manner, when the substrate is exposed to the first elevated temperature, the volatile components of the displacement solution, such as water and the non-aqueous solvent, as well as any residual water or residual solvents from the aqueous wash solution which may be present, are removed to deposit the fill materials in substantially solid form within the spaces 14 between the high aspect ratio features 12. The first heat treatment step may be carried out in an ambient air atmosphere or, alternatively, may be carried out in a vacuum or in an inert atmosphere under nitrogen or other inert gas, for example.

Referring to FIG. 4, the substrate is shown after the first heat treatment step in which only substantially solid fill material 20 remains within the spaces 14 between the high aspect ratio features 12, with the fill material either partially or substantially filling the spaces, as shown to the left in FIG. 4, or completely filling the spaces, as shown to the right in FIG. 4. Advantageously, the substantially solid fill material physically supports the high aspect ratio features and prevents their collapse during this and subsequent stages of the present process.

In a final step, the fill material is removed via a plasma ashing process, for example, oxygen plasma under argon. The plasma ashing process may be carried out in an ambient air atmosphere or, alternatively, may be carried out in a vacuum or in an inert atmosphere under nitrogen or other inert gas, for example.

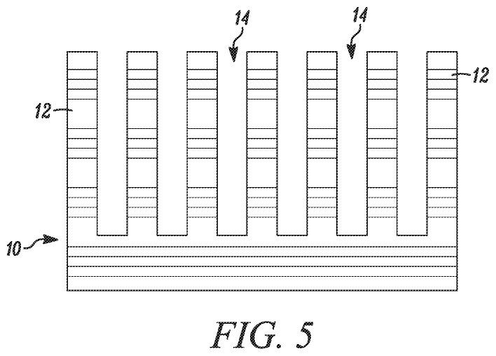

Referring to FIG. 5, after the fill material is completely removed from spaces 14 between high aspect ratio features 12 of substrate 10, spaces 14 will be completely empty, with the geometry of the high aspect ratio features 12 preserved without collapse. Substrate 10 may then be subjected to further downstream processing steps as desired.

Advantageously, the present fill materials have been found to facilitate relatively high ashing (removal) rates and are therefore suitable for removal using plasma and may be readily stripped using oxidizing or reducing plasma conditions. In this manner, because the ashing rate is higher, the substrate is exposed to the plasma for a shorter amount of time than in known processes, which mitigates or eliminates the removal of silicone from substrate 10 or its features 12, thereby preserving the resolution or geometry of the features 12.

As used herein, the phrase “within any range defined between any two of the foregoing values” literally means that any range may be selected from any two of the values listed prior to such phrase regardless of whether the values are in the lower part of the listing or in the higher part of the listing. For example, a pair of values may be selected from two lower values, two higher values, or a lower value and a higher value.

The following non-limiting Examples serve to illustrate the disclosure.

### EXAMPLES

### Example 1

### Viscosity and Film Thickness Study

Coating formulations 1-10 in Table 1 below were prepared by dissolving the ingredients in the weight proportions as listed.

| Formulation no., | | | | n- | | | |
|---|---|---|---|---|---|---|---|
| polymer type, | | | | propyl | | | Propylene |
| molecular weight | Polymer | Isopropyl | Water | alcohol | Surfactant | PGMEA | glycol |
| (Daltons) | (wt. %) | alcohol (wt. %) | (wt. %) | (wt. %) | (wt. %) | (wt. %) | (wt. %) |
| 1-PVP, 2,500 | 10.0 | 90.0 | | | | | |
| 2-PVP, 10,000 | 8.5 | 91.5 | | | | | |
| 3-PVP, 10,000 | 10.0 | 81.0 | 9.0 | | | | |
| 4-PVP, 5,000 | 8.3 | 80.6 | | | 1.3 | 5.6 | 4.2 |
| 5-PVP, 15,000 | 8.3 | 80.6 | | | 1.3 | 5.6 | 4.2 |
| 6-PVP, 10,000 | 8.3 | 80.6 | | | 1.3 | 5.6 | 4.2 |
| 7-PVP, 2,500 | 20.0 | | 16.0 | 64.0 | | | |
| 8-PVP, 10,000 | 20.0 | | 16.0 | 64.0 | | | |
| 9-PVP, 10,000/ | 9.7/2.3 | | 88.0 | | | | |
| PVA | | | | | | | |
| 10-PAAM, | 15.0 | | 85.0 | | | | |
| 10,000 | | | | | | | |

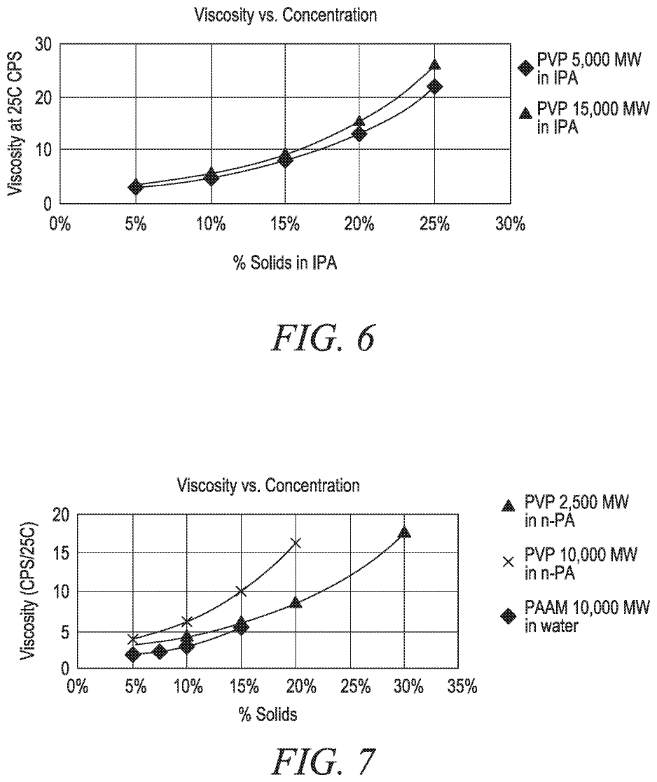

The viscosity of the formulated solutions was determined using a Brookfield spindle-type viscometer of the type described herein. Viscosity data as a function of wt. % solids concentration for formulations similar to those in Table 1 is set forth in FIGS. 6 and 7, which formulations included only the polymers, solvents, and relative concentrations indicated in FIGS. 6 and 7, wherein it may be seen that viscosity generally progressively increases with increasing solid concentration in each formulation.

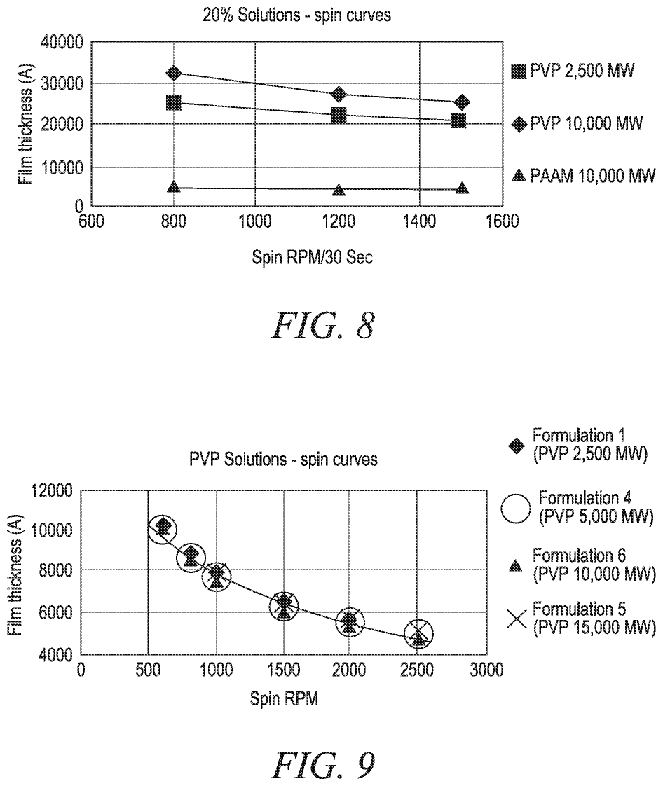

Formulations similar to, or listed above in Table 1, were coated on bare silicon wafers and film thickness as a function was spin speed in revolutions per minute (rpm) was collected after baking the films at 160° C. and 180° C. for 60 seconds each using two hot plates sequentially, with the results presented in FIGS. 8 and 9 below. In FIG. 8, 20 wt. % solutions were prepared of PVP and PAAM in the indicated solvents with no other components. In FIG. 9, Formulations 1 and 4-6 from Table 1 above were used. As may be seen from FIGS. 8 and 9, film thickness progressively decreases with spin speed.

Finally, the coatings were deposited on a high aspect resolution (HAR) pattern and, after baking and removing the films using oxygen plasma strip chemistry no toppling of structures was noticed.

As used herein, the singular forms “a”, “an” and “the” include plural unless the context clearly dictates otherwise. Moreover, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the disclosure be limited to the specific values recited when defining a range.

The foregoing description is only illustrative of the present disclosure. Various alternatives and modifications can be devised by those skilled in the art without departing from the disclosure. Accordingly, the present disclosure is intended to embrace all such alternatives, modifications and variances that fall within the scope of the appended claims.

What is claimed is:

1. A method for preventing collapse of semiconductor substrate features, comprising the steps of:
providing a patterned semiconductor substrate having a plurality of high aspect ratio features with spaces between the features, the gap spaces at least partially filled with an initial fluid;
displacing the initial fluid with a displacement solution including at least one primary solvent and at least one first fill material in the form of a water-soluble polymer having a weight average molecular weight (Mw) between 1,000 and 15,000 Daltons, as determined by gel permeation chromatography (GPC), the displacement solution further having a viscosity of less than 100 centipoise;
exposing the substrate to an elevated temperature to substantially remove the solvent from the spaces and deposit the fill material in substantially solid form within the spaces; and
exposing the substrate to a dry ash process to remove the fill material from the gap spaces.

2. The method of claim 1, wherein the at least one water-soluble polymer is selected from the group consisting of polyvinylpyrrolidone (PVP), polyacrylamide (PAAM), and a combination thereof.

3. The method of claim 1, wherein the elevated temperature is between 100° C. and 280° C.

4. The method of claim 1, wherein the at least one solvent comprises water.

5. The method of claim 1, wherein the at least one solvent comprises at least one non-aqueous solvent.

6. The method of claim 1, wherein the at least one solvent comprises water and at least one non-aqueous solvent.

7. The method of claim 1, wherein the displacement solution includes between 5 wt. % and 30 wt. % of the fill material, based on the total weight of the displacement solution.

8. The method of claim 1, wherein the displacement solution has a viscosity of less than 50 centipoise.

9. A displacement solution for use in preventing collapse of semiconductor substrate features, comprising:
at least one water-soluble polymer having a weight average molecular weight (Mw) between 1,000 and 15,000 Daltons, as determined by gel permeation chromatography (GPC);
at least one primary solvent;
at least one secondary solvent;
at least on surfactant; and
the displacement solution having a viscosity of less than 100 centipoise.

10. The displacement solution of claim 9, wherein the at least one water-soluble polymer is selected from the group consisting of polyvinylpyrrolidone (PVP), polyacrylamide (PAAM), and a combination thereof.

11. The displacement solution of claim 9, wherein the at least one polymer is present in an amount of between 5 wt. % and 30 wt. %, based on an overall weight of the displacement solution.

12. The displacement solution of claim 9, wherein the at least one primary solvent is present in an amount of between 70 wt. % and 95 wt. %, based on an overall weight of the displacement solution.

13. The displacement solution of claim 9, wherein the at least one water-soluble polymer has a weight average molecular weight (Mw) between 2,500 and 10,000 Daltons, as determined by gel permeation chromatography (GPC).

14. The displacement solution of claim 9, wherein the at least one water-soluble polymer has a weight average molecular weight (Mw) between 4,000 and 6,000 Daltons, as determined by gel permeation chromatography (GPC).

15. The displacement solution of claim 9, having a viscosity less than 50 centipoise.
